(19) United States
(12) Patent Application Publication
(10) Pub. No.: US 2026/0188624 A1
(43) Pub. Date: Jul. 2, 2026

(54) PROCESS CHAMBER AND SUBSTRATE PROCESSING APPARATUS

(71) Applicant: SEMES CO., LTD., Cheonan-si (KR)

(72) Inventors: Sang Hyon JEON, Cheonan-si (KR); Sang Min HA, Hwaseong-si (KR); Soo Ill JANG, Asan-si (KR)

(73) Assignee: SEMES CO., LTD., Cheonan-si (KR)

(21) Appl. No.: 19/429,226

(22) Filed: Dec. 22, 2025

(30) Foreign Application Priority Data
Dec. 26, 2024 (KR) 10-2024-0197660

(51) Int. Cl. H01J 37/32; B65G 47/90; H10P 72/00

(52) U.S. Cl. CPC H01J 37/32477; B65G 47/90; H10P 72/0404; H01J 2237/0266

(57) ABSTRACT

Provided is a process chamber. The process chamber includes: a chamber process unit where a process unit for processing a substrate is provided; a chamber driving unit including a driving mechanism involved in an operation of the process unit and providing an inner space in which the driving mechanism is disposed; and a wall-shaped chamber control unit for controlling the operation of the process unit and defining the inner space.

### CROSS-REFERENCE TO RELATED APPLICATION

This application claims priority to and the benefit of Korean Patent Application No. 10-2024-0197660 filed in the Korean Intellectual Property Office on Dec. 26, 2024, the entire contents of which are incorporated herein by reference.

### TECHNICAL FIELD

The present invention relates to a process chamber and a substrate processing apparatus.

### BACKGROUND ART

In order to manufacture a semiconductor device, various processes are performed. For example, processes for forming a pattern on a substrate, such as a cleaning process, an etching process, a photo process, and a deposition process, are performed on a substrate, such as a wafer. The process is performed in a process chamber. The substrate is loaded into the process chamber. The process chamber forms a pattern on the substrate by supplying a treatment liquid, a coating liquid, a plasma, and the like to the substrate.

FIG. 1 is a diagram schematically illustrating a general process chamber. Referring to FIG. 1, a general process chamber 1000 includes a chamber process unit 1100, a chamber driving unit 1200, and a control unit 1300. A substrate is loaded into the chamber process unit 1100. The chamber process unit 1100 performs processing on a substrate W. The chamber driving unit 1200 is provided with a driving device, such as a motor, for operating various process units provided in the chamber process unit 1100, a pipe device through which a liquid treating a substrate flows, and the like.

Meanwhile, an electric unit 1400 is disposed above the process chamber 1000. The electric unit 1400 is supported by a support member 1500 installed on the chamber process unit 1100. The electric unit 1400 transmits a control signal to the chamber driving unit 1200 to control process units provided to the chamber process unit 1100. The control unit 1300 may include an E-CAT device. The control unit 130 mediates the signal transmission between the electric unit 1400 and the chamber driving unit 1200. The control unit 1300 is connected to the chamber driving unit 1200 and the electric unit 1400 by first and second cables 1001 and 1002, respectively.

However, the above-described device structure has limitations in miniaturization. This is because the electric unit 1400 is disposed above the process chamber 1000, and thus the volume influence by the electric unit 1400 is high. Furthermore, when a plurality of process chambers 1000 is stacked in a vertical direction in a tower shape, the electric unit 1400 is connected to each of the plurality of process chambers 1000. In this case, the lengths of the second cables 1002 connected to each process chamber 1000 are different. In this case, even if the control signal is transmitted to the chamber driving unit 1200 at the same time, a difference may occur at a time point when the control signal reaches the chamber driving unit 1200. Furthermore, when maintenance is performed on the process chamber 1000, wiring operations, such as connection and separation of the first and second cables 1001 and 1002, are required. Furthermore, since the electric unit 1400 is disposed above the process chamber 1000, when maintenance on the electric unit 1400 is performed, the work risk increases.

In addition, EMC noise generated by driving devices, such as motors, of the chamber driving unit 1200 may enter the first and second cables 1001 and 1002, and this noise may affect the control unit 1300 and the electric unit 1400.

### SUMMARY OF THE INVENTION

The present invention has been made in an effort to provide a process chamber and a substrate processing apparatus that may be miniaturized.

The present invention has also been made in an effort to provide a process chamber and a substrate processing apparatus in which a wire structure with the same length and shape may be applied to a plurality of process chambers.

The present invention has also been made in an effort to provide a process chamber and a substrate processing apparatus capable of simplifying wiring work required when a worker performs maintenance and minimizing the risk of work.

The present invention has also been made in an effort to provide a process chamber and a substrate processing apparatus capable of increasing electrical noise durability in response to disposition of control devices in a narrow wall space.

The objectives of the present disclosure are not limited thereto and other objectives not stated herein may be clearly understood by those skilled in the art from the following description.

Further, an exemplary embodiment of the present disclosure, a process chamber may comprising, a chamber process unit where a process unit for processing a substrate is provided; a chamber driving unit including a driving mechanism involved in an operation of the process unit and providing an inner space in which the driving mechanism is disposed; and a wall-shaped chamber control unit for controlling the operation of the process unit and defining the inner space.

Further, an exemplary embodiment of the present disclosure, an apparatus for processing a substrate, the apparatus comprising: an index module including a load port on which a container accommodating a substrate is placed and a robot that unloads the substrate from the container; and a process module disposed side by side with the index module and having a plurality of process chambers, wherein the plurality of process chambers is disposed in a horizontal direction and/or a vertical direction, at least one of the plurality of process chambers may include: a chamber process unit where a process unit for processing a substrate is provided; a chamber driving unit including a driving mechanism involved in an operation of the process unit and providing an inner space in which the driving mechanism is disposed; and a wall-shaped chamber control unit for controlling the operation of the process unit and defining the inner space.

Further, an exemplary embodiment of the present disclosure, a substrate processing apparatus for liquid-treating a substrate, the substrate processing apparatus comprising: an index module including a load port on which a container accommodating a substrate is placed and a robot that unloads the substrate from the container; and a process module disposed side by side with the index module and having a plurality of process chambers, wherein the plurality of process chambers is disposed in a horizontal direction and/or a vertical direction, the plurality of process chambers includes: a chamber process unit where a process unit for processing a substrate is provided; a chamber driving unit including a driving mechanism involved in an operation of the process unit and providing an inner space in which the driving mechanism is disposed; and a wall-shaped chamber control unit for controlling the operation of the process unit and defining the inner space, the chamber driving unit and the chamber control unit are disposed under the chamber process unit, and the chamber driving unit and the chamber control unit are disposed side by side along a horizontal direction, the chamber control unit includes: a control device connection unit to which a wire connected to the driving mechanism is connected; and a control device board unit configured to be detachable from the control device connection unit, configured to be slidable along a sliding guide of the chamber driving unit, and selectively opening and closing the inner space, the control device board unit includes: a board unit wall that provides a wall space; a communication circuit unit that is disposed in the wall space and communicatively connected to an external controller; and a chamber driving circuit unit for receiving a control data signal from the communication circuit unit and controlling the driving mechanism; an insulating cover that is disposed to face the inner space outside the board unit wall and blocks external noise; and a shielding cover that is disposed to face the inner space in the wall space and made of a metal material, a first ground line for removing the noise is connected to the shielding cover, a second ground line for removing noise introduced through the wire is connected to the chamber driving circuit unit, and a third ground line that communicates the communication circuit unit with the controller and removes communication noise introduced through the controller may be connected to the communication circuit unit.

According to the exemplary embodiment of the present invention, it is possible to miniaturize a process chamber and a substrate processing apparatus.

Further, according to the exemplary embodiment of the present invention, it is possible to apply a wire structure with the same length and shape to a plurality of process chambers.

Further, according to the exemplary embodiment of the present invention, it is possible to simplify wiring work required when a worker performs maintenance and minimize the risk of work.

Further, according to the exemplary embodiment of the present invention, it is possible to increase electrical noise durability in response to disposition of control devices in a narrow wall space.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a diagram schematically illustrating a general process chamber.

FIG. 2 is a top plan view illustrating a substrate processing apparatus according to an exemplary embodiment of the present invention.

FIG. 3 is a side view of the substrate processing apparatus of FIG. 2.

FIG. 4 is a perspective view of a process chamber for describing an arrangement structure of a chamber process unit, a chamber driving unit, and a chamber control unit of the process chamber of FIG. 2.

FIG. 5 is a diagram illustrating an example of process units disposed in the chamber process unit of the process chamber of FIG. 2.

FIG. 6 is a diagram illustrating an internal structure of the chamber driving unit and the chamber control unit of FIG. 5 viewed from one direction.

FIG. 7 is a diagram illustrating an internal structure of a control device board unit and a control device connection unit of the chamber control unit of FIG. 5, viewed from another direction.

FIG. 8 is a side view illustrating a substrate processing apparatus according to another exemplary embodiment of the present invention.

FIG. 9 and FIG. 10 are diagrams illustrating another example of process units disposed in the chamber process unit of the process chamber of FIG. 2.

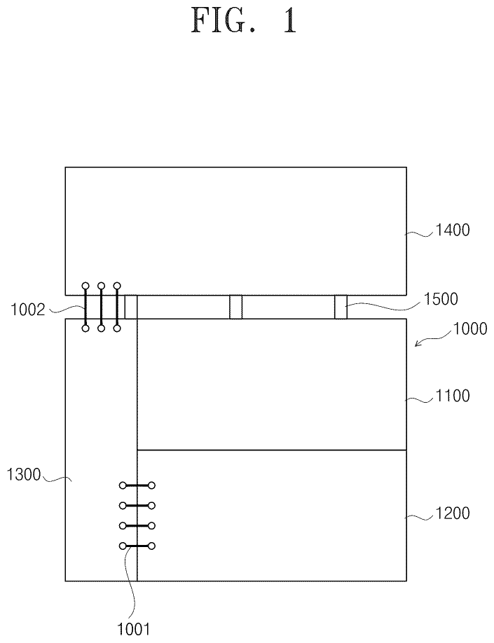

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

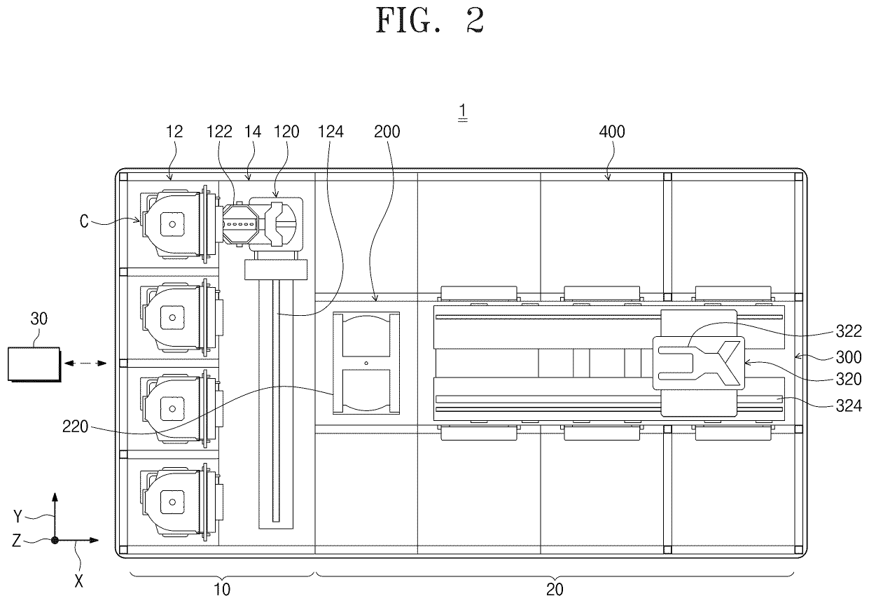

Hereinafter, a substrate processing apparatus 1 according to an exemplary embodiment of the present invention will be described with reference to FIGS. 2 to 10. The substrate processing apparatus 1 may perform a liquid treatment process of processing the substrate W by supplying a liquid to the substrate W, or a plasma treatment process of processing the substrate W by supplying plasma to the substrate W. Hereinafter, a process in which the substrate treatment apparatus 1 performs a liquid treatment process on the substrate W will be described as an example. The liquid treatment process may be a cleaning process for cleaning the substrate W by supplying a cleaning liquid, such as deionized water, IPA, or chemical, to the substrate W.

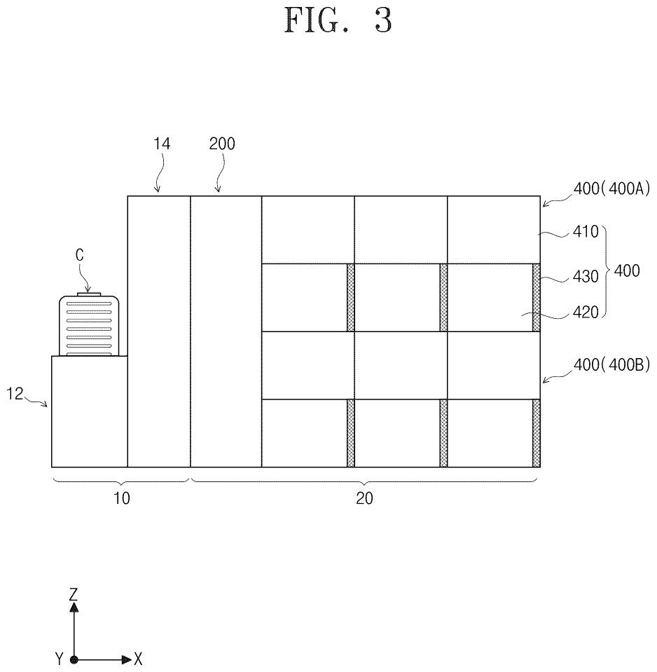

FIG. 2 is a top plan view illustrating the substrate processing apparatus according to an exemplary embodiment of the present invention, and FIG. 3 is a side view of the substrate processing apparatus of FIG. 2.

Referring to FIGS. 2 and 3, the substrate processing apparatus 1 includes an index module 10, a treating module 20, and a controller 30. When viewed from above, the index module 10 and the treating module 20 are disposed along one direction. Hereinafter, the direction in which the index module 10 and the treating module 20 are disposed is referred to as a first direction X, and when viewed from above, a direction perpendicular to the first direction X is referred to as a second direction Y, and a direction perpendicular to both the first direction X and the second direction Y is referred to as a third direction Z.

The index module 10 transfers a substrate W from a container C in which the substrate W is accommodated to the treating module 20, and makes the substrate W, which has been completely processed in the treating module 20, be accommodated in the container C. A longitudinal direction of the index module 10 is provided in the second direction Y. The index module 10 includes a load port 12 and an index frame 14. Based on the index frame 14, the load port 12 is located at a side opposite to the treating module 20. The container C in which the substrates W are accommodated is placed in the load port 12. The load port 12 may be provided in plural, and the plurality of load ports 12 may be disposed in the second direction Y.

As the container C, an airtight container, such as a Front Open Unified Pod (FOUP), may be used. The container C may be placed on the load port 12 by a transfer means (not illustrated), such as an overhead transfer, an overhead conveyor, or an automatic guided vehicle, or an operator.

An index robot 120 is provided to the index frame 14. A guide rail 124 of which a longitudinal direction is the second direction Y is provided within the index frame 14, and the index robot 120 may be provided to be movable on the guide rail 124. The index robot 120 includes a hand 122 on which the substrate M is placed, and the hand 122 may be provided to be movable forward and backward, rotatable about the third direction Z, and movable along the third direction Z. The plurality of hands 122 is provided while being spaced apart from each other in the up and down direction, and is capable of independently moving forward and backward.

The controller 30 controls the substrate processing apparatus 1. The controller 30 may include a process controller formed of a microprocessor (computer) that executes the control of the substrate processing apparatus 1, a user interface formed of a keyboard in which an operator performs a command input operation or the like in order to manage the substrate processing apparatus 1, a display for visualizing and displaying an operation situation of the substrate processing apparatus 1, and the like, and a storage unit storing a control program for executing the process executed in the substrate processing apparatus 1 under the control of the process controller or a program, that is, a treating recipe, for executing the process in each component according to various data and treating conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory. The controller 30 may control the process units provided in the process chamber 400 so that the processing process for the substrate W may be performed in the process chamber 400 to be described later.

The treating module 20 includes a buffer unit 200, a transfer chamber 300, and a process chamber 400. The buffer unit 200 provides a space in which the substrate W loaded into the treating module 20 and the substrate W unloaded from the treating module 20 stay temporarily. The process chamber 400 performs a liquid treatment process of liquid-treating the substrate W by supplying a liquid onto the substrate W. The transfer chamber 300 transfers the substrate W between the buffer unit 200 and the process chamber 400.

The transfer chamber 300 may be provided so that a longitudinal direction is the first direction X. The buffer unit 200 may be disposed between the index module 10 and the transfer chamber 300. The process chamber 400 may be disposed on a side portion of the transfer chamber 300. The process chamber 400 may be disposed in the second direction Y. The buffer unit 200 may be located at one end of the transfer chamber 300.

According to the example, the process chambers 400 are respectively disposed on opposite sides of the transfer chamber 300. At one side of the transfer chamber 300, the process chambers 400 may be provided in an array of A×B (each of A and B is 1 or a natural number larger than 1) in the first direction X and the third direction Z. In the illustrated example, the process chambers 400 are arranged in a 3×2 arrangement. The process chamber 400 disposed at an upper side based on the third direction Z may be referred to as an upper process chamber 400A, and the process chamber 400 disposed at a lower side may be referred to as a lower process chamber 400B. In the exemplary embodiment of the present invention, the substrate processing apparatus 1 may have a tower-shaped chamber arrangement having the upper process chamber 400A and the lower process chamber 400B.

The transfer chamber 300 includes a transfer robot 320. A guide rail 324 having a longitudinal direction in the first direction X is provided in the transfer chamber 300, and the transfer robot 320 may be provided to be movable on the guide rail 324. The transfer robot 320 includes a hand 322 on which the substrate W is placed, and the hand 322 may be provided to be movable forward and backward, rotatable about the third direction Z, and movable along the third direction Z. The plurality of hands 322 is provided while being spaced apart from each other in the vertical direction, and is capable of independently moving forward and backward.

The buffer unit 200 includes a plurality of buffers 220 on which the substrate W is placed. The buffers 220 may be disposed while being spaced apart from each other in the third direction Z. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

The process chamber 400 performs treatment process on a substrate W. The transfer robot 320 of the transfer chamber 300 may unload the substrate W from the buffer unit 200 and load the substrate W into the process chamber 400.

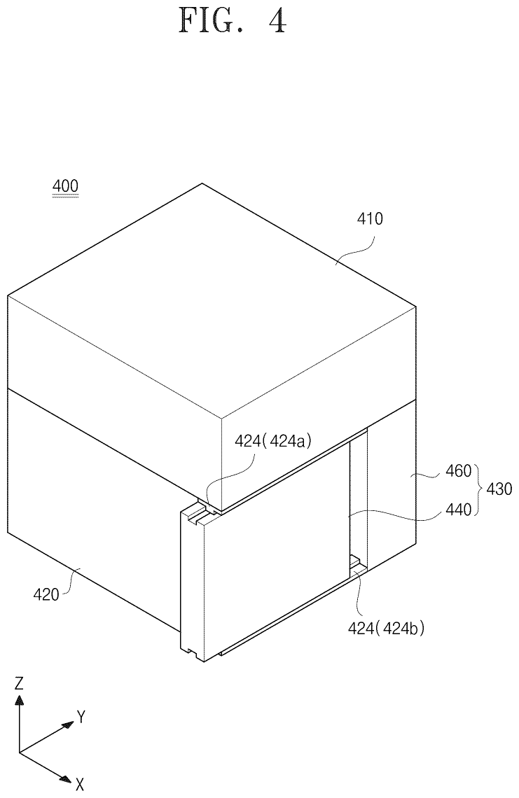

FIG. 4 is a perspective view of a process chamber for describing an arrangement structure of a chamber process unit, a chamber driving unit, and a chamber control unit of the process chamber of FIG. 2.

Referring to FIGS. 3 and 4, the process chamber 400 includes a chamber process unit 410, a chamber driving unit 420, and a chamber control unit 430. The chamber process unit 410 performs processing on the substrate W. Process units to be described later are provided in the chamber process unit 410. The chamber driving unit 420 includes driving mechanisms that are involved in operations of the process units provided in the chamber process unit 410. The chamber control unit 430 may receive control data from the external controller 30 and control the driving mechanisms included in the chamber driving unit 420. The chamber process unit 410 is disposed on the chamber driving unit 420 and the chamber control unit 430. The chamber driving unit 420 and the chamber control unit 430 may be arranged side by side in a horizontal direction, for example, the first direction X.

The chamber control unit 430 may have a wall shape. The chamber control unit 430 may be provided on a side portion of the chamber driving unit 420. The chamber control unit 430 may form at least a portion of an inner space 421a to be described later. The chamber control unit 430 includes a control device board unit 440 and a control device connection unit 460. The control device connection unit 460 is fixedly installed in the chamber driving unit 420 by fixing means, such as a bolt or a nut. The control device board unit 440 is configured to be detachable from the control device connection unit 460. Specifically, the control device board unit 440 is configured to be slidable in the second direction Y along a sliding guide 424 provided in the chamber driving unit 420. Sliding grooves having shapes corresponding to an upper sliding guide 424a and a lower sliding guide 424b are formed at upper and lower portions of the control device board unit 440, respectively.

The control device board unit 440 and the control device connection unit 460 are each provided in the form of a wall defining at least a portion of the inner space 421a to be described later. When the control device board unit 440 is separated from the control device connection unit 460, the inner space 421a, which will be described later, may be opened to the outside. That is, the chamber control unit 430 itself may function as a wall defining the inner space 421a of the chamber driving unit 420. Furthermore, the control device board unit 440 and/or the control device connection unit 460 has a thickness of about several cm in the first direction X. For example, the control device board unit 440 and/or the control device connection unit 460 may have a thickness of about 5 cm or less.

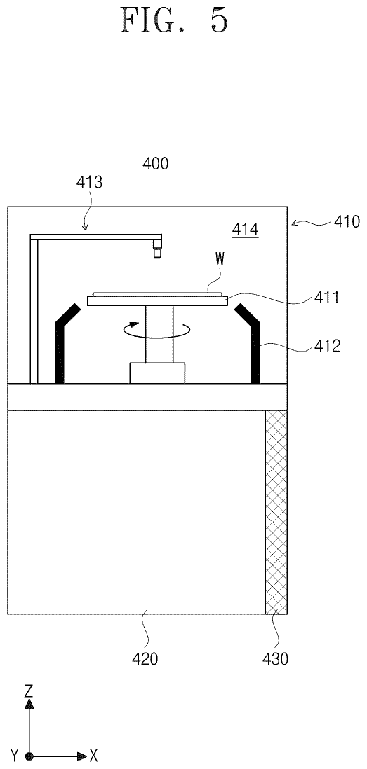

FIG. 5 is a diagram illustrating an example of process units disposed in the chamber process unit of the process chamber of FIG. 2.

The process chamber 400 may process the substrate W. The process chamber 400 is configured to perform at least one of various processes for forming a pattern on the substrate W, which may be a wafer. For example, the process chamber 400 may perform liquid treatment on the substrate W. The liquid treatment may be a cleaning process for removing impurities attached to the substrate W or a coating process for forming a coating film on the substrate W. Alternatively, the process chamber 400 may perform plasma treatment on the substrate W. The plasma treatment may be an etching or ashing process for removing a film on the substrate W, or a deposition process for forming a thin film on the substrate W.

When the process chamber 400 performs a liquid treatment process as described above, the chamber process unit 410 provides a treatment space 414 in which the substrate W is processed. In the treatment space 414, process units for liquid-treating the substrate W may be provided. For example, the process unit may be a spin chuck 411 for supporting and rotating the substrate W, a bowl 412 for collecting a process liquid collected supplied to the substrate W and scattered and provided to be movable in the up-down direction, and a liquid supply unit 413 including a nozzle for supplying a treatment liquid to the substrate W. However, the type of process unit is not limited to the above, and various process units that may be used to perform processing on the substrate W may be applied to the process chamber 400.

Hereinafter, the chamber driving unit 420 and the chamber control unit 430 will be described in more detail. As described above, the chamber control unit 430 includes the control device board unit 440 and the control device connection unit 460.

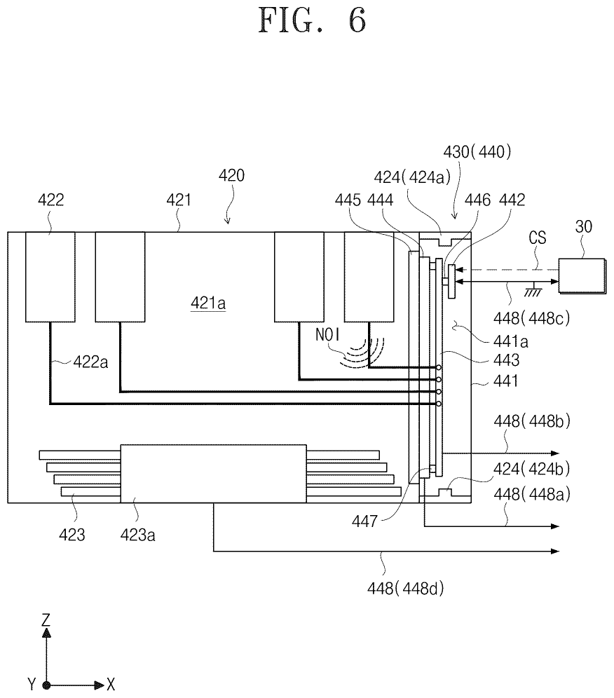

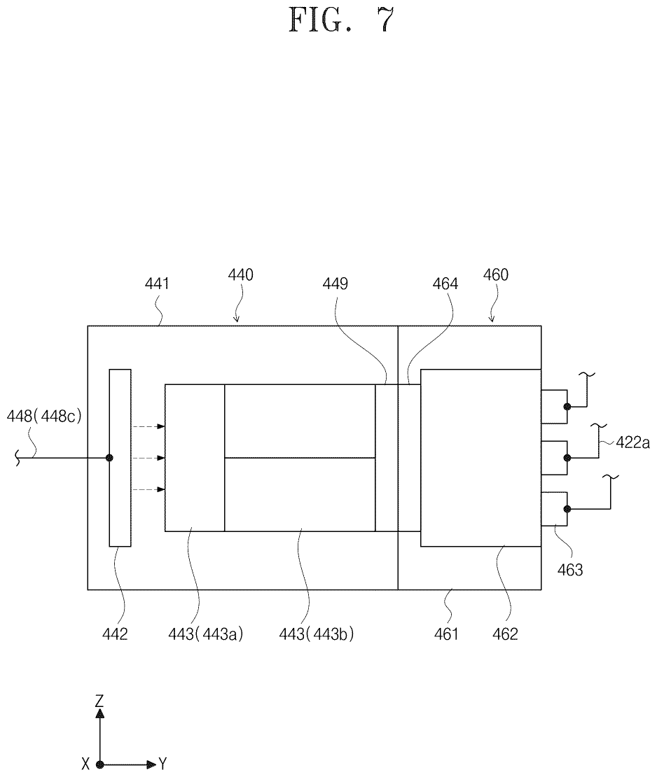

FIG. 6 is a diagram illustrating an internal structure of the chamber driving unit and the chamber control unit of FIG. 5 viewed from one direction, and FIG. 7 is a diagram illustrating an internal structure of the control device board unit and the control device connection unit of the chamber control unit of FIG. 5, viewed from another direction.

Referring to FIGS. 6 and 7, the chamber driving unit 420 includes various driving mechanisms which are involved in the operation of the process units provided in the chamber process unit 410. The chamber driving unit 420 includes a housing 421, a driving device 422, a pipe device 423, and a sliding guide 424.

The housing 421 provides an inner space 421a. The housing 421 is provided in a generally rectangular parallelepiped shape. The inner space 421a may be defined by the housing and the chamber control unit 430 described above. In the inner space 421a, driving mechanisms that are involved in the operations of the process units described above are disposed. The driving device 422 and the pipe device 423 may be examples of driving mechanisms.

The driving device 422 is disposed in the inner space 421a. The driving device 422 may be a device that transmits power to the above-described process unit. For example, the driving device 422 may be a motor or a pneumatic cylinder. The driving device 422 may be a device that generates power that is involved in a movement of a process unit. Any one of the driving devices 422 may change a position of a nozzle included in the liquid supply unit 413. The other of the driving devices 422 may rotate the spin chuck 411. Another driving device 422 may chuck the substrate W using a chuck pin or the like that may be provided in the spin chuck 411. Another driving device 422 may adjust the height of the bowl 412.

As described above, the driving devices 422 may implement operations of the process units implementing the processing of the substrate W. Although the installation position of the driving device 422 may be variously changed, the driving device 422 may be installed in an upper portion of the inner space 421a to be adjacent to the chamber process unit 410. A plurality of driving devices 422 may be provided, and each of the driving devices 422 may be connected to the chamber control unit 430 through a driving device cable 422a.

The pipe device 423 may be involved in operations related to the liquid supply and discharge of the process unit. The pipe device 423 may supply a treatment liquid, which is a fluid supplied to the liquid supply unit 413. In addition, the pipe device 423 may discharge the treatment liquid collected by the bowl 412. The pipe device 423 includes a pipe through which a fluid flows, and a pipe ground part 423a configured to cover at least a portion of the pipe.

The pipe ground part 423a may be made of a metal material surrounding the pipe. Meanwhile, a treatment liquid flows through the pipe, and static electricity may be generated due to friction between the treatment liquid and the pipe. When the static electricity is carried to the substrate W by the treatment liquid, a pattern formed on the substrate W may be damaged. Accordingly, the pipe ground part 423a may be connected with a fourth ground line 448d for removing static electricity. Further, the pipe device 423 may include an auto valve for controlling the flow of the fluid flowing through the pipe. The valve may be turned on/off or an opening amount may be adjusted under the control of the controller 30 described above. The valve is connected with a wire, such as a cable, that may be connected to the control device connection unit 460, to be controlled by the controller 30.

Furthermore, the chamber driving unit 420 includes the sliding guide 424 as described above. The sliding guide 424 includes the upper sliding guide 424a and the lower sliding guide 424b, and may be provided at positions corresponding to upper and lower portions of the control device board unit 440 to be described below, respectively. The sliding guide 424 extends along the second direction Y. Accordingly, the control device board unit 440 may be configured to be slidable along the second direction Y. If necessary, a ground line may be connected to the sliding guide 424. Friction may occur when the control device board unit 440 is detached. Due to the friction, static electricity may be generated, which may be removed through a ground line connected to the sliding guide 424.

The chamber control unit 430 includes a control device board unit 440 and the control device connection unit 460. The control device board unit 440 and the control device connection unit 460 are arranged side by side in the second direction Y.

The control device board unit 440 may control driving mechanisms provided in the chamber driving unit 420 from the external controller 30.

The control device board unit 440 includes a board unit wall 441, a communication circuit unit 442, a chamber driving circuit unit 443, a shield cover 444, and an insulating cover 445. The communication circuit unit 442 and the chamber driving circuit unit 443 may be circuit units including a communication means, such as a processor, a recording medium, and a LAN card, and a circuit structure. The communication circuit unit 442 and the chamber driving circuit unit 443 may be spaced apart from each other by the first insulating member 446. Furthermore, the chamber driving circuit unit 443 and the shield cover 444 to be described later may be spaced apart from each other by a second insulating member 447.

The board unit wall 441 is provided in the form of a thin wall. The board unit wall 441 provides a wall space 441a therein. The board unit wall 441 may have a generally rectangular parallelepiped shape. The board unit wall 441 may be provided to have a thin thickness of about several cm in the first direction X. The board unit wall 441 may be provided to have a thickness of about 5 cm or less. The communication circuit unit 442 and the chamber driving circuit unit 443 are provided in the wall space 441a provided by the board unit wall 441.

If necessary, the surfaces of the board unit wall 441 may be made of different materials. For example, among the surfaces of the board unit wall 441, the surface facing the inner space 421a is made of a material, such as ceramic, having low thermal conductivity, and among the surfaces of the board unit wall 441, the surface (or surfaces) not facing the inner space 421a may be made of a metal material having excellent thermal conductivity. Since the wall space 441a of the board unit wall 441 is a very narrow space, the wall space 441a may be easily overheated. Therefore, it may be important to dissipate heat generated in the wall space 441a to the outside and to block external heat from flowing into the wall space 441a.

Accordingly, among the surfaces of the board unit wall 441, the surface facing the inner space 421a is made of a material, such as ceramic, with low thermal conductivity to block the heat generated from the chamber driving unit 420 from entering the wall space 441a, and among the surfaces of the board unit wall 441, the surface (or surfaces) not facing the inner space 421a is made of a metal material with excellent thermal conductivity, so that heat release is made in a direction away from the inner space 421a.

The communication circuit unit 442 may be communicatively connected to the external controller 30 through a communication line 448c. The communication circuit unit 442 may receive the control data signal CS transmitted by the controller 30 through the communication line 448c. The control data signal CS may be transmitted to the communication circuit unit 442 in the form of a voltage signal. The communication circuit unit 442 may receive the control data signal CS transmitted by the controller 30 and transmit the received control data signal CS to the chamber driving circuit unit 443. The controller 30 and the communication circuit unit 442 may be directly communicatively connected through the communication line 448c, or unlike this, a separate control unit may be provided between the controller 30 and the communication circuit unit 442. In this case, the controller 30 and the control unit, and the control unit and the communication circuit unit 442 may be connected to each other through the communication line 448c. The controller 30 may be communicatively connected to the communication circuit unit 442 through the control unit.

The chamber driving circuit unit 443 may generate a control signal for controlling the above-described driving mechanisms from data transmitted by the controller 30, and control the above-described driving mechanisms based on the generated control signal. The chamber driving circuit unit 443 may include an ESD protector and an Isolator element.

The chamber driving control circuit unit 443 includes a chamber control signal processing circuit unit 443a and a chamber driving driver circuit unit 443b. The chamber control signal processing circuit unit 443a may receive the above-described control data signal CS and generate a control signal for controlling driving mechanisms based on the received control data signal CS. The generated control signal is transmitted to the chamber driving driver circuit unit 443b. The chamber driving driver circuit unit 448b may control the operation of the above-described driving mechanisms based on the transmitted control signal. For example, the chamber driving driver circuit unit 448b may operate a motor, which may be the driving device 422 described above, or may control opening and closing of an auto valve included in the pipe device 423. A plurality of chamber driving driver circuit units 443b may be provided. Each chamber driving driver circuit unit 443b may be provided according to a type of driving mechanism. For example, the chamber driving driver circuit unit 443b may be provided to correspond to each type of driving mechanism, such as a circuit unit corresponding to a motor and a circuit unit corresponding to a cylinder.

The control signal transmitted from the chamber driving driver circuit unit 443b to the driving mechanism may be transmitted via the control device connection unit 460. The control device connection unit 460 and the control device board unit 440 may be selectively connected to each other. The control device board unit 440 may include a first docking unit 449, and the control device connection unit 460 may include a second docking unit 464. The first docking unit 449 and the second docking unit 464 may be I/O connectors.

Meanwhile, an insulating cover 445 made of an insulating material for blocking external noise NOI may be provided outside the board unit wall 441. The insulating cover 445 may be attached to a portion of the surfaces of the board unit wall 441, which faces the inner space 421a. The driving device 422, which may be a motor, may generate electromagnetic noise NOI while driving. The insulating cover 445 may minimize the electromagnetic noise NOI from being introduced into the wall space 441a and affecting the chamber driving circuit unit 443.

Also, the shielding cover 444 made of a metal material may be disposed inside the wall space 441a. The shielding cover 444 is configured to remove electromagnetic noise NOI that has not been blocked by the insulating cover 445 through a first ground line 448a to be described later.

The shielding cover 444 and the insulating cover 445 are integrally provided with the board unit wall 441, and are configured to be separated together when the control device board unit 440 is separated from the control device connection unit 460.

The control device connection unit 460 includes a connection wall 461, a connector board 462, and a connection port 463 in addition to the second docking part 464 described above.

The connecting wall 461 may have a thickness that is the same as or similar to that of the board unit wall 441. The connection unit wall 461 may provide a wall space therein similarly to the board unit wall 441, and the connector board 462 may be installed in the wall space. The control signal transmitted by the chamber driving driver circuit unit 443b may be transmitted to the connector board 462 through the first and second docking units 449 and 464. The control signal transmitted to the connector board 462 may be transmitted to the wires, such as the driving device cable 422a, through the connection port 463 connected to the connector board 462. The control signal transmitted through the wire may control the operation of the driving device 422 and/or the pipe device 423.

Meanwhile, a triple ground structure is provided to the chamber control unit 430. Specifically, three ground lines 448 may be connected to the chamber control unit 430.

Among the ground lines 448, the first ground line 448a is connected to the shielding cover 444 described above. As described above, the external noise NOI is primarily blocked by the insulating cover 445. The noise NOI that is not blocked due to the insulating cover 445 flows into the shielding cover 444, and the noise NOI introduced into the shielding cover 444 may be removed through the first ground line 448a.

The second ground line 448b among the ground lines 448 is connected to the chamber driving circuit unit 443. The second ground line 448b may be connected to the chamber control signal processing circuit unit 443a and/or the chamber driving driver circuit unit 443b. In some cases, the second ground line 448b may also be connected to the connector board 462. As described above, the driving device 422 is connected to the chamber control unit 430 through the driving device cable 422a, and EMC noise may be introduced through the driving device cable 422a. The introduced noise may be removed to the outside through the second ground line 448b connected to the chamber driving circuit unit 443.

Among the ground lines 448, the third ground line 448c is connected to the communication circuit unit 442. The third ground line 448c may be the communication line 448c described above. A ground path may be connected to the communication line 448c. EMC noise, which is external communication noise introduced through the controller 30, may be removed to the outside through the third ground line 448c.

The triple ground structure as described above enables noise removal most effectively by separately providing a ground conduction path according to each noise and electrostatic generator. Therefore, noise durability may be improved compared to a single ground in the device.

The process chamber 400 according to the exemplary embodiment of the present invention includes the chamber control unit 430 having a wall shape. The chamber control unit 430 performs not only a function as a wall defining the inner space 422a of the chamber driving unit 420 but also a function as an electric device necessary to control the chamber driving unit 420. Accordingly, since a separate electric unit does not need to be provided on the upper side of the process chamber 400, miniaturization of the substrate processing apparatus 1 is possible.

In addition, in the present invention, each of the process chambers 400 includes the chamber driving unit 420 and the chamber control unit 430. As the chamber control unit 430 is provided in each of the process chambers 400, the wire structures between the chamber control units 430 and the chamber driving unit 420 between the process chambers may be made the same. Therefore, it is possible to solve a technical problem that an error may occur in process control between the process chambers 400 as the length and shape of the wire are changed. In addition, in the related art, it was necessary for a worker to repeatedly separate and connect wires provided in the process chamber 400 during maintenance, but in the present invention, the control device board unit 440 of the chamber control unit 430 is easily detachable, thereby minimizing inconvenience that may occur during maintenance.

In addition, in the present invention, various circuit configurations, such as the communication circuit unit 442 and the chamber driving circuit unit 443, are disposed in the narrow wall space 441a having a thickness of several cm. When the plurality of circuit configurations is disposed in a narrow space, durability against external noise may be weakened. In order to solve this problem, the present invention improves electrical noise durability by applying the triple ground structure to the chamber control unit 430.

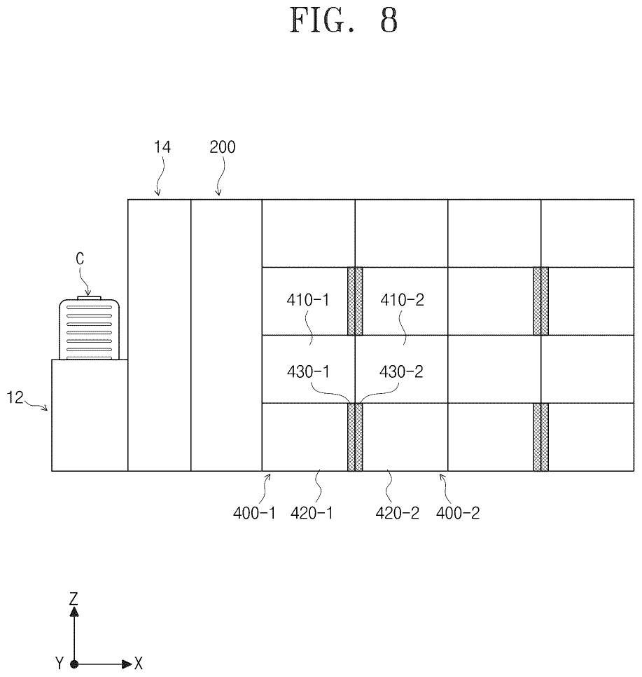

In the above-described example, the present invention has been described based on the case where the arrangement of the chamber control unit 430 provided in the plurality of process chambers 400 is the same as an example, but the present invention is not limited thereto. For example, as illustrated in FIG. 8, the first process chamber 400-1 may include a first chamber process unit 410-1, a first chamber driving unit 420-1, and a first chamber control unit 430-1, and the second process chamber 400-2 adjacent to the first process chamber 400-1 may include a second chamber process unit 410-2, a second chamber driving unit 420-2, and a second chamber control unit 430-2. In addition, the first chamber control unit 430-1 and the second chamber control unit 430-2 may be disposed at positions facing each other. In this case, since the worker may separate both the first chamber control unit 430-1 and the second chamber control unit 430-2 from one position, the time required for maintenance may be further shortened.

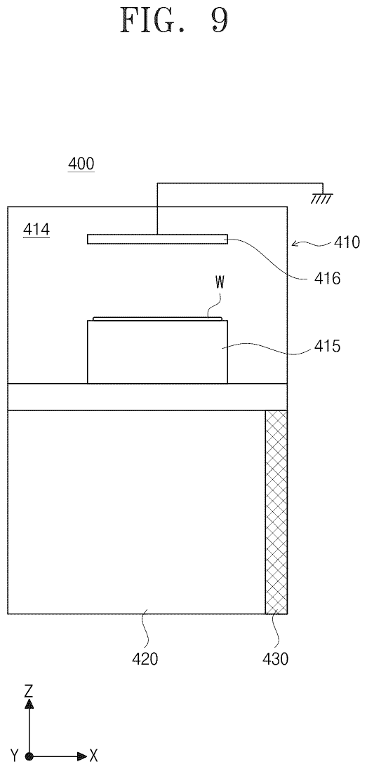

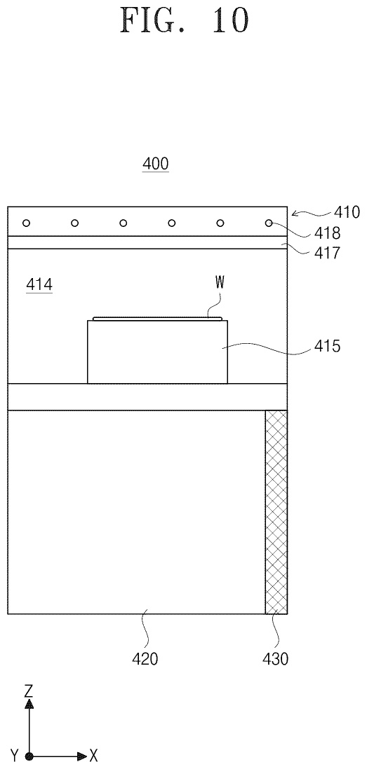

In the above-described example, the present invention has been described based on the case where the process chamber 400 performs liquid treatment on the substrate W as an example, but the present invention is not limited thereto. For example, as illustrated in FIG. 9, the process chamber 400 may be provided as a CCP type plasma chamber. In this case, the chamber process unit 410 may include a lower electrode 415 and an upper electrode 416 facing the lower electrode 415. Alternatively, as illustrated in FIG. 10, the process chamber 400 may be provided as an ICP type plasma chamber. In this case, the chamber process unit 410 may include a lower electrode 415, an antenna 418 for generating plasma, and a dielectric plate 417 installed between the antenna 418 and the lower electrode 415.

It should be understood that exemplary embodiments are disclosed herein and other modifications may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present disclosure, and all such modifications that would be obvious to one of ordinary skill in the art are intended to be included within the scope of the accompanying claims.

What is claimed is:

1. A process chamber comprising:
a chamber process unit where a process unit for processing a substrate is provided;
a chamber driving unit including a driving mechanism involved in an operation of the process unit and providing an inner space in which the driving mechanism is disposed; and
a chamber control unit configured to control the operation of the process unit and configured as a wall that defines the inner space.

2. The process chamber of claim 1, wherein the chamber control unit includes:
a control device connection unit to which a wire connected to the driving mechanism is connected; and
a control device board unit configured to be detachable from the control device connection unit and to selectively open and close the inner space..

3. The process chamber of claim 2, wherein the control device board unit is configured to be slidable along a sliding guide of the chamber driving unit.

4. The process chamber of claim 2, wherein the control device board unit includes:
a board unit wall that provides a wall space;
an insulating cover disposed on an outer side of the board unit wall and facing the inner space and blocks external noise; and
a shielding cover disposed within the wall space and facing the inner space and made of a metal material

5. The process chamber of claim 4, wherein a first ground line for removing the external noise is connected to the shielding cover.

6. The process chamber of claim 5, wherein the control device board unit includes:
a communication circuit unit that is disposed in the wall space and communicatively connected to an external controller; and
a chamber driving circuit unit configured to receive a control data signal from the communication circuit unit and control the driving mechanism, and
a second ground line configured to remove noise introduced through the wire is connected to the chamber driving circuit unit.

7. The process chamber of claim 6, wherein a third ground line that communicates the communication circuit unit with the controller and removes communication noise introduced through the controller is connected to the communication circuit unit.

8. The process chamber of claim 1, wherein the driving mechanism includes:
a driving device configured to provide driving force to the process unit; and
a pipe device configured to supply fluid to the process unit or collecting fluid discharged from the process unit,
the pipe device includes:
a pipe through which the fluid flows; and
a pipe ground unit configured to cover at least a portion of the pipe, and
a fourth ground line configured to remove static electricity generated in the pipe is connected to the pipe ground unit.

9. The process chamber of claim 1, wherein the chamber driving unit and the chamber control unit are disposed under the chamber process unit.

10. The process chamber of claim 9, wherein the chamber driving unit and the chamber control unit are disposed side by side along a horizontal direction.

11. The process chamber of claim 1, wherein the chamber process unit is configured to liquid-treat the substrate with a treatment liquid.

12. An apparatus for processing a substrate, the apparatus comprising:
an index module including a load port on which a container accommodating a substrate is placed and a robot that unloads the substrate from the container; and
a process module disposed side by side with the index module and having a plurality of process chambers,
wherein the plurality of process chambers is disposed in a horizontal direction and/or a vertical direction,
at least one of the plurality of process chambers includes:
a chamber process unit where a process unit for processing a substrate is provided;
a chamber driving unit including a driving mechanism involved in an operation of the process unit and providing an inner space in which the driving mechanism is disposed; and
a chamber control unit configured to control the operation of the process unit and configured as a wall that defines the inner space.

13. The apparatus of claim 12, wherein at least a part of the chamber control unit is configured to be detachable from the chamber driving unit and to selectively open and close the inner space.

14. The apparatus of claim 13, wherein the chamber control unit includes:
a control device connection unit to which a wire connected to the driving mechanism is connected; and
a control device board unit configured to be detachable from the control device connection unit and selectively opening and closing the inner space.

15. The apparatus of claim 14, wherein the control device board unit includes:
a board unit wall that provides a wall space;
a communication circuit unit that is disposed in the wall space and communicatively connected to an external controller; and
a chamber driving circuit unit connected with the communication circuit unit, and
the chamber driving circuit unit includes:
a chamber control signal processing circuit unit which is disposed in the wall space, and receives a control data signal from the communication circuit unit and generates a control signal to control the driving mechanism; and
a chamber driving driver circuit unit which is disposed in the wall space and receives the control signal and operates the driving mechanism.

16. The apparatus of claim 15, wherein the control device board unit includes a first docking unit connected to the control device connection unit, and
the control device connection unit includes a second docking unit that faces the first docking unit and is selectively connected to the first docking unit when the control device board unit is attached/detached.

17. The apparatus of claim 15, wherein the control device board unit includes:
an insulating cover disposed on an outer side of the board unit wall and facing the inner space and blocks external noise; and
a shielding cover disposed within the wall space and facing the inner space and made of a metal material.

18. The apparatus of claim 17, wherein a first ground line for removing the noise is connected to the shielding cover,
a second ground line for removing noise introduced through the wire is connected to the chamber driving circuit unit, and
a third ground line that communicates the communication circuit unit with the controller and removes communication noise introduced through the controller is connected to the communication circuit unit.

19. The apparatus of claim 12, wherein the chamber driving unit and the chamber control unit are disposed under the chamber process unit, and
the chamber driving unit and the chamber control unit are disposed side by side along a horizontal direction.

20. A substrate processing apparatus for liquid-treating a substrate, the substrate processing apparatus comprising:
an index module including a load port on which a container accommodating a substrate is placed and a robot that unloads the substrate from the container; and
a process module disposed side by side with the index module and having a plurality of process chambers,
wherein the plurality of process chambers is disposed in a horizontal direction and/or a vertical direction,
the plurality of process chambers includes:
a chamber process unit where a process unit for processing a substrate is provided;
a chamber driving unit including a driving mechanism involved in an operation of the process unit and providing an inner space in which the driving mechanism is disposed; and
a chamber control unit configured to control the operation of the process unit and configured as a wall that defines the inner space,
the chamber driving unit and the chamber control unit are disposed under the chamber process unit, and
the chamber driving unit and the chamber control unit are disposed side by side along a horizontal direction,
the chamber control unit includes:
a control device connection unit to which a wire connected to the driving mechanism is connected; and
a control device board unit configured to be detachable from the control device connection unit and to selectively open and close the inner space.,
the control device board unit includes:
a board unit wall that provides a wall space;
a communication circuit unit that is disposed in the wall space and communicatively connected to an external controller; and
a chamber driving circuit unit for receiving a control data signal from the communication circuit unit and controlling the driving mechanism;
an insulating cover disposed on an outer side of the board unit wall and facing the inner space and blocks external noise; and
a shielding cover disposed within the wall space and facing the inner space and made of a metal material,
a first ground line for removing the noise is connected to the shielding cover,
a second ground line for removing noise introduced through the wire is connected to the chamber driving circuit unit, and
a third ground line that communicates the communication circuit unit with the controller and removes communication noise introduced through the controller is connected to the communication circuit unit.
